(19) United States
(12) Patent Application Publication
(10) Pub. No.: US 2025/0098266 A1
(43) Pub. Date: Mar. 20, 2025

(54) GROUP III-N DEVICE INCLUDING SOURCE CONTACT CONNECTED TO SUBSTRATE THROUGH TRENCH

(71) Applicant: TEXAS INSTRUMENTS INCORPORATED, Dallas, TX (US)

(72) Inventors: Zhikai Tang, Sunnyvale, CA (US); Jungwoo Joh, Allen, TX (US); Ujwal Radhakrishna, San Jose, CA (US)

(21) Appl. No.: 18/756,202

(22) Filed: Jun. 27, 2024

Related U.S. Application Data
(60) Provisional application No. 63/582,982, filed on Sep. 15, 2023.

(51) Int. Cl. H01L 29/417; H01L 29/20; H01L 29/40; H01L 29/66; H01L 29/778

(52) U.S. Cl. CPC H10D 64/254; H10D 30/015; H10D 30/475; H10D 62/8503; H10D 64/01

(57) ABSTRACT

Semiconductor devices with a source contact extending into a substrate are described. In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A gate stack is disposed over the barrier layer in the gate region. A source contact in the source region extends into the semiconductor substrate, including a first contact with a 2DEG in the heterojunction structure and a second contact with the semiconductor substrate.

### CROSS-REFERENCE TO RELATED APPLICATIONS

This non-provisional application claims priority based upon U.S. provisional Application No. 63/582,982, filed on Sep. 15, 2023, which is hereby incorporated by reference in its entirety.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift rate, high breakdown voltage, high thermal conductivity, robust chemical and thermal stability, etc. Due to these characteristics, III-N materials are being considered as promising materials for fabrication of powerful high-frequency transistor structures capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to III-N semiconductor devices with a source contact extending into a substrate by way of a deep trench structure. In one example, a semiconductor device comprises a semiconductor substrate including a source region, a gate region, a drain region and a drain access region between the drain region and the gate region, where a heterojunction structure is disposed over the semiconductor substrate. The heterojunction structure includes a buffer layer over the semiconductor substrate and a barrier layer over the buffer layer. A gate stack is disposed over the barrier layer in the gate region. A source contact in the source region extends into the semiconductor substrate, where the source contact includes a first contact with a 2DEG in the heterojunction structure and a second contact with the semiconductor substrate.

In one example, a method of fabricating a semiconductor device is disclosed. The method comprises, among others, forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer; forming a gate stack over the barrier layer in the gate region; and forming a source contact in the source region extending into the semiconductor substrate, where the source contact includes a first contact with a 2DEG in the heterojunction structure and a second contact with the semiconductor substrate. In some arrangements, the source contact may be formed before forming a gate electrode coupled to the gate stack. In some arrangements, the gate electrode may be formed before forming the source contact (and drain contact in some examples).

In one example, a semiconductor device is disclosed, which comprises, among others, a first III-N unit cell formed over a first area of a semiconductor substrate, the first III-N unit cell including a first source contact in a source region of the first area, where the first source contact is connected to the semiconductor substrate through a trench extended into the semiconductor substrate; and a second III-N unit cell formed over a second area of the semiconductor substrate, the second III-N unit cell including a second source contact in a source region of the second area, where the first and second III-N unit cells are coupled together with a common gate.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1K depict cross-sectional views of a semiconductor device including a GaN device at various stages of a process flow according to a first example of the present disclosure;

FIGS. 2A-2H depict cross-sectional views of a semiconductor device including a GaN device at various stages of a process flow according to a second example of the present disclosure;

FIGS. 3A-3J depict cross-sectional views of a semiconductor device including a GaN device at various stages of a process flow according to a third example of the present disclosure;

FIGS. 4A-4I depict cross-sectional views of a semiconductor device including a GaN device at various stages of a process flow according to a fourth example of the present disclosure;

FIGS. 5 and 6 depict layouts of example semiconductor devices comprising GaN unit cells according to some examples of the present disclosure;

FIGS. 7A and 7B depicts layouts of example semiconductor devices including multiple GaN unit cells according to some examples of the present disclosure; and

FIGS. 8A-8D are flowcharts of methods of fabricating a semiconductor device according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or RDSON), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2DEG beneath the gate at zero or negative gate bias. Applying a positive gate voltage enhances the 2DEG under the gate and turns the EMODE GaN device on to allow current flow between the source and drain.

In some examples, a GaN device may be formed with one or more GaN layers over a suitable semiconductor substrate, e.g., including a silicon substrate. In this approach and for proper operation, an electrical contact or contacts is (are) desirable from higher layers in the device to the semiconductor substrate. For example, such contacts permit maintaining constant bias in the substrate and enable the GaN device(s) to handle higher currents. However, integrating suitable contacts with respect to the substrates while attaining desired circuit density has been challenging.

Substrate contact connections (which may be referred to as substrate connections or substrate contacts) are particularly important for GaN power devices. In some examples, substrate connections may be realized by a through-GaN via process in a dedicated non-active region of the die, which can lead to a reduction in the die area for the active device regions. In order to mitigate the die area loss due to substrate connections, the number of through-GaN vias may be limited in an example implementation. However, reducing the number of substrate connections and/or distributing the substrate connections outside the active area may negatively impact the specific on-resistance (Rsp) performance of the GaN device, especially in architectures that include several unit cells, e.g., on the order of hundreds or thousands of unit cells. As the Rsp values increase, the charging/discharging of parasitic capacitances may also increase and potentially become non-uniform, resulting in degradation in the switching performance of the GaN device.

Examples of the present disclosure recognize the foregoing challenges and provide an integrated substrate contact solution where a source contact and a substrate contact are integrated in a deep trench structure formed in a source region of a semiconductor device. In some arrangements, a metallization process is provided that connects the 2DEG of a device and the substrate (e.g., in case of discrete devices) or a doped well (e.g., N-well or P-well) in the substrate of an IC device. As there is no need for dedicated non-active areas for through-via substrate connections, which may be distributed and/or shared among several unit cells in some examples, the source-to-substrate resistance for each individual unit cell may be rendered more uniform, thus improving the switching performance of the device. Substrate bias effects may also become more uniform as each unit cell is provided with its own substrate connection. Moreover, thermal performance may also be improved because of the segregated nature of the thermal resistance paths of a GaN device, which helps bypass high thermal impedance paths and/or locations of a baseline GaN device. Whereas the examples herein may provide various structures, materials and processes that may engender these and other beneficial effects in a variety of device modes, no particular result is a requirement unless explicitly recited in a particular claim.

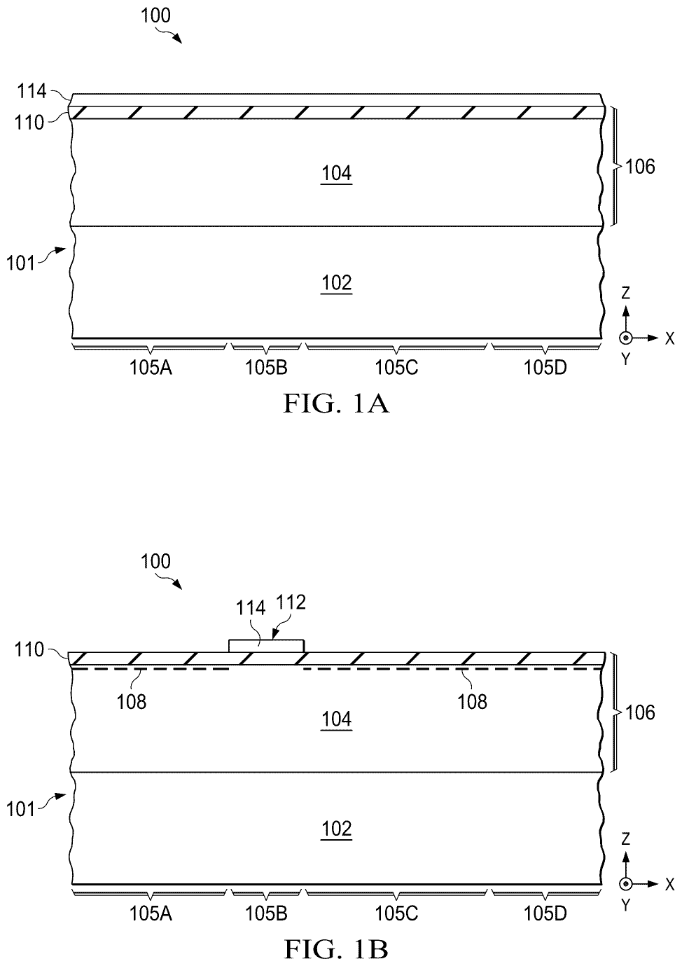

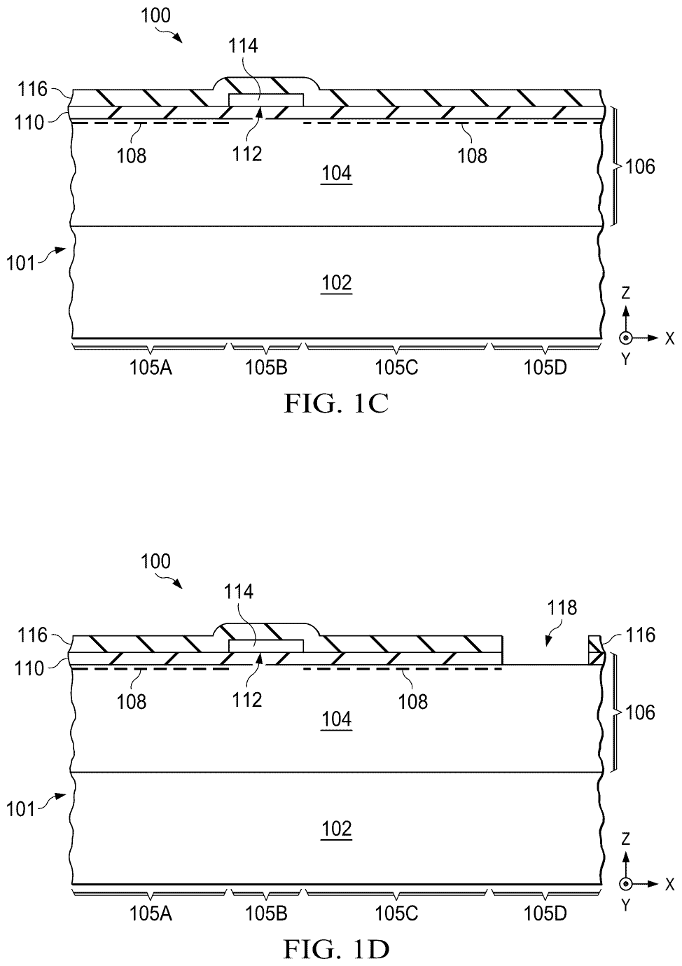

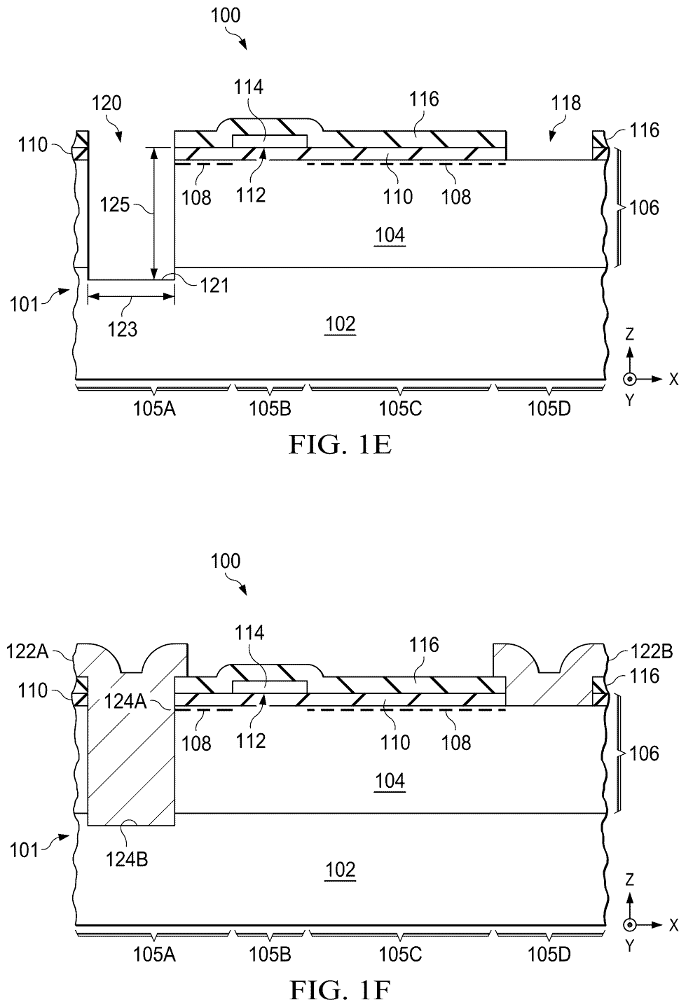

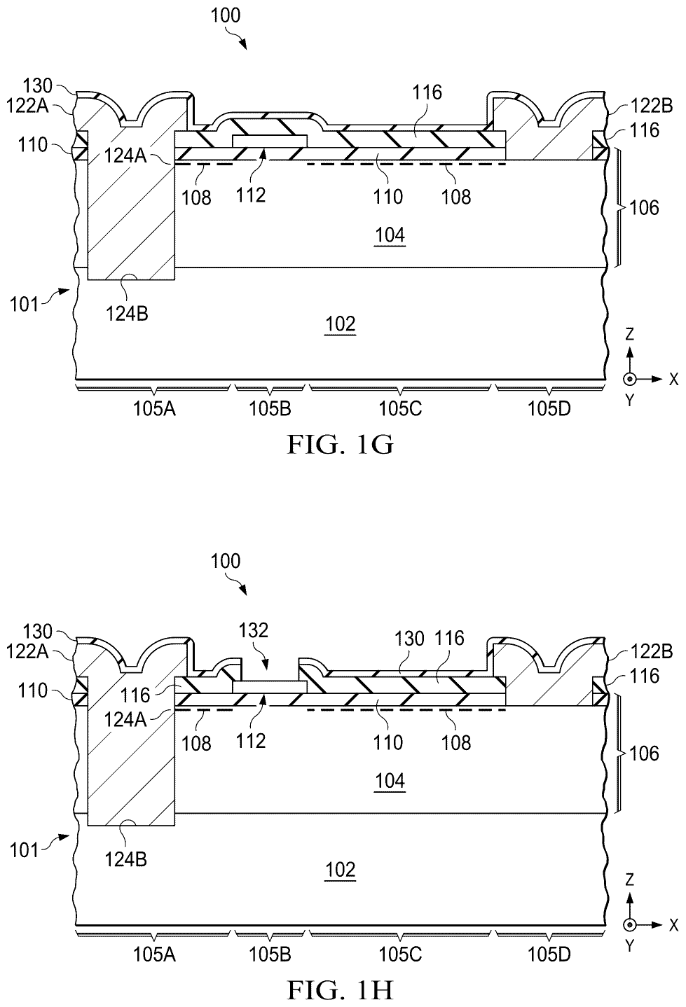

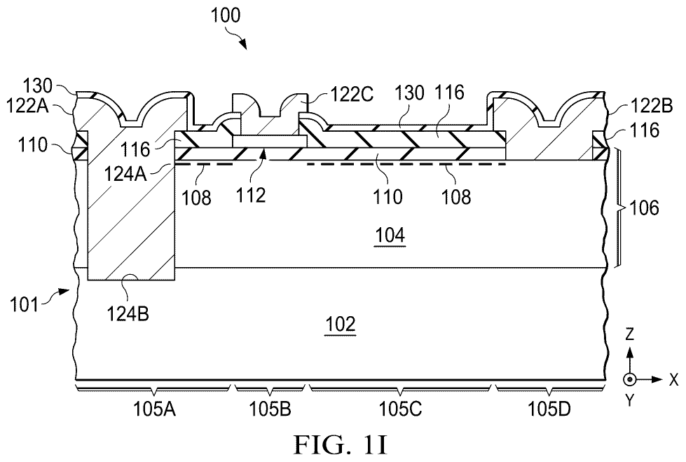

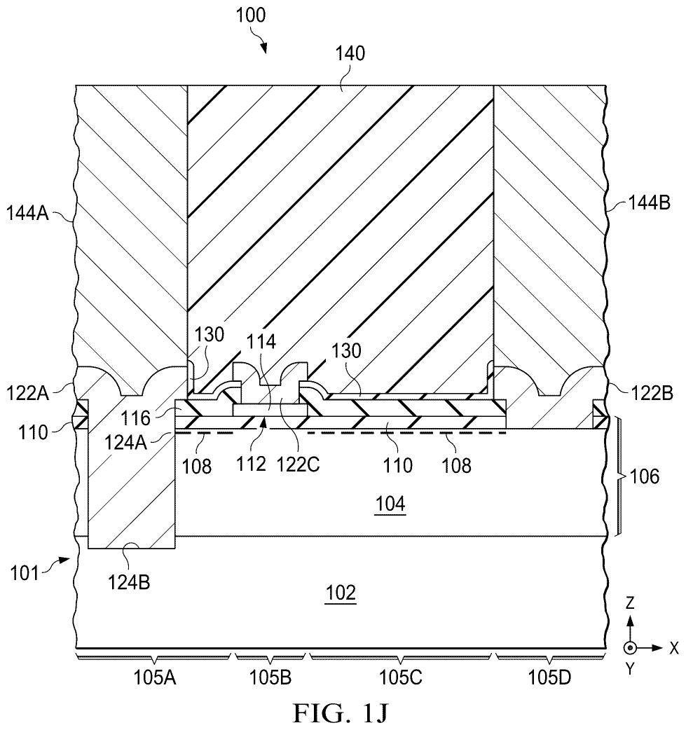

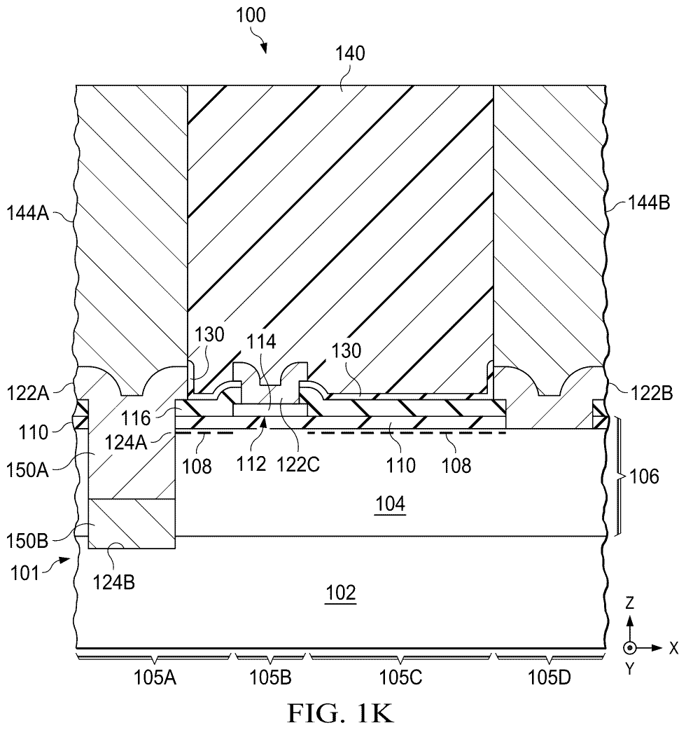

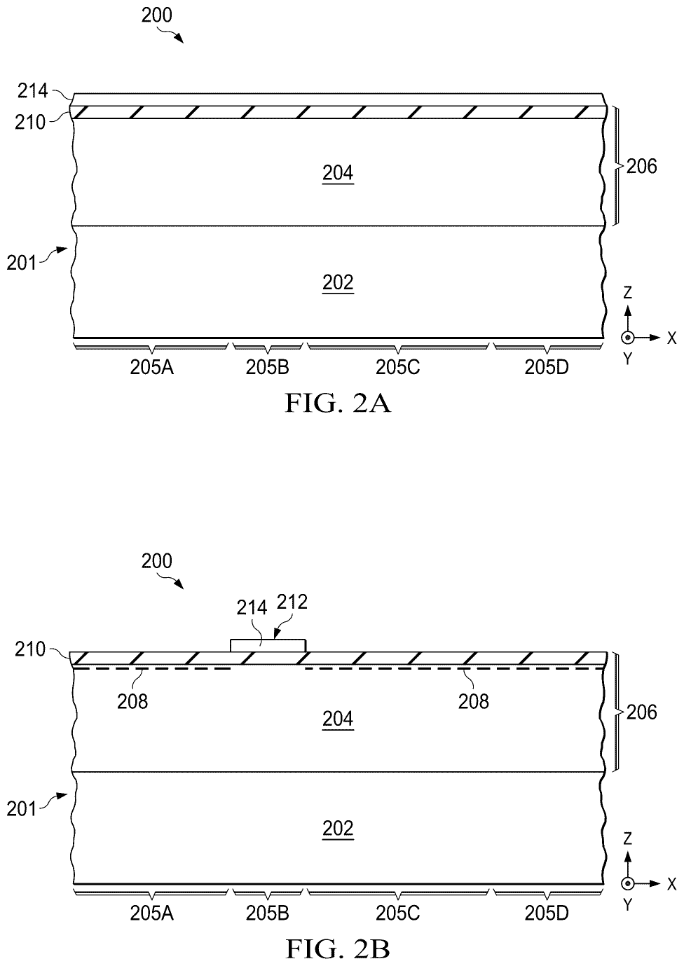

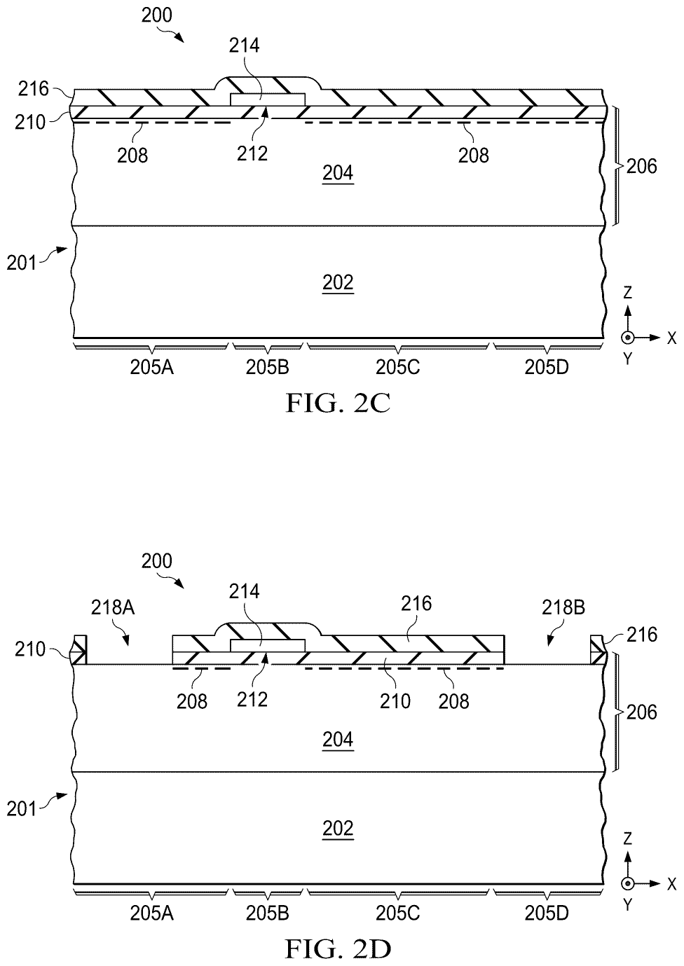

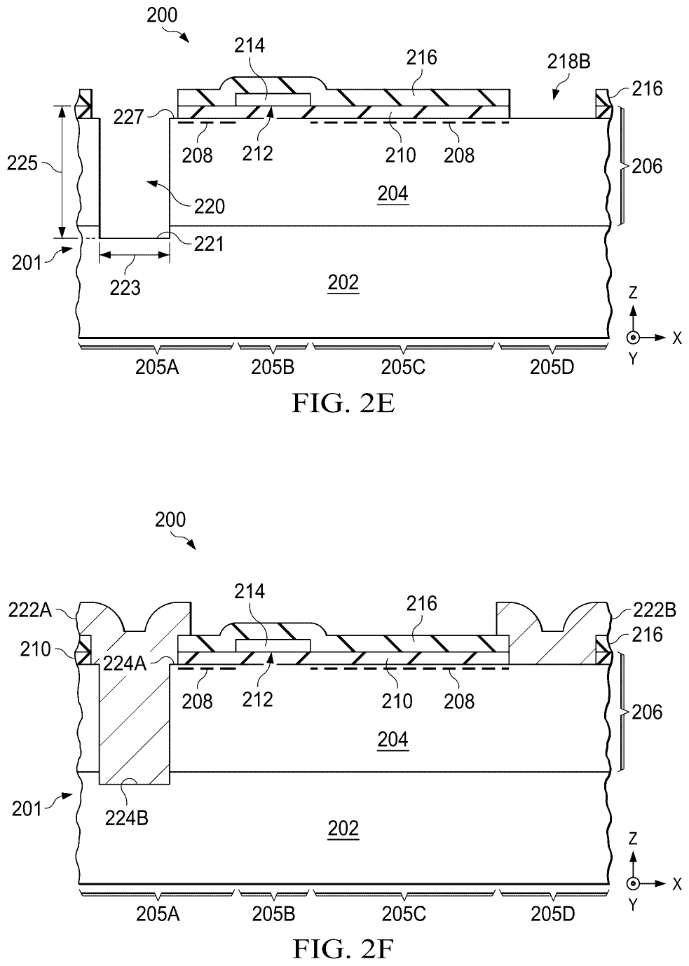

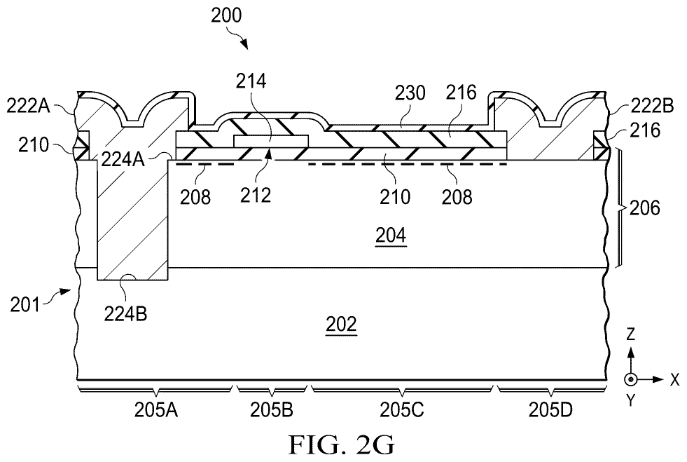

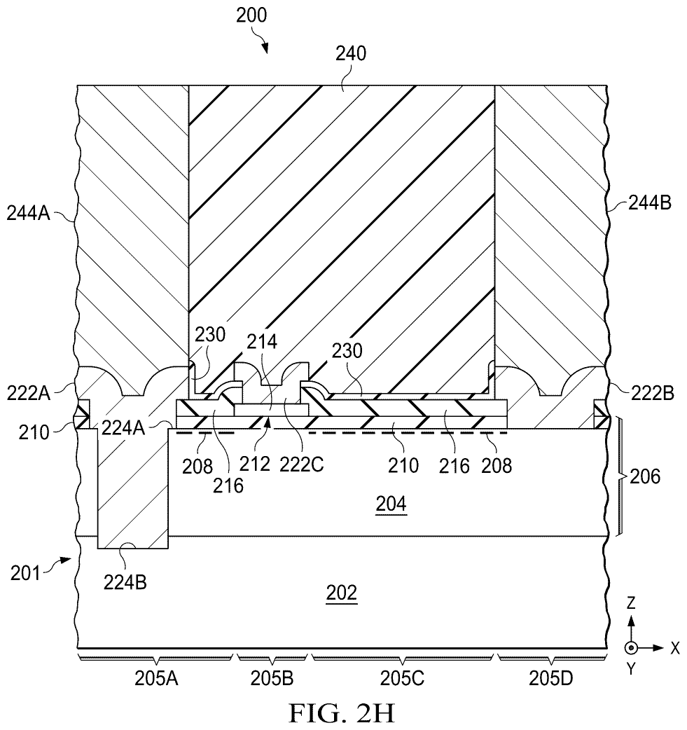

Turning to the drawings, FIGS. 1A-1K depict cross-sectional views of a semiconductor device 100 including a GaN device 101 at various stages of a process flow according to a first example of the present disclosure. By way of illustration, the GaN device 101 may be fabricated as an EMODE device where a substrate-connected source contact may be provided in a deep trench formed in a source region of the GaN device for purposes herein. In similar manner, cross-sectional views of FIGS. 2A-2H, 3A-3J, and 4A-4I depict semiconductor devices 200, 300, and 400, respectively, at various stages of a process flow according to additional and/or alternative examples of the present disclosure, where a substrate-connected source contact may be provided in a deep trench formed in a source region. As will be set forth in detail below, the fabrication of a substrate-connected source contact may be integrated within a GaN process flow at different stages depending on implementation. In general, a substrate-connected source contact, also referred to as a substrate-tied source contact or a deep trench source contact in some examples, may be fabricated before the formation of a gate electrode or after the formation of a gate electrode of a GaN device. An example process where the deep trench source (DTS) contact, e.g., a source contact in the source region extending into the substrate, is formed prior to forming a gate electrode may be referred to as a “gate last” process. Analogously, an example process where the DTS contact is formed after forming the gate electrode may be referred to as a “gate first” process. Regardless of the integration stage with respect to the formation of a DTS contact, representative examples herein may be configured to provide an integrated source contact structure that includes a first contact (e.g., a first portion of the deep trench source contact) coupled with a 2DEG of the device and a second contact (e.g., a second portion of the deep trench source contact) coupled with the substrate, which may be scaled to a variety of device architectures as will be set forth below.

Referring to FIGS. 1A-1K in particular, an example “gate last” process of the present disclosure is set forth in detail below. FIG. 1A depicts an early intermediate stage of the semiconductor device 100 formed on a portion of a semiconductor substrate 102, which may be provided as a silicon wafer, a silicon-on-sapphire wafer, or a silicon carbide wafer, and/or as semiconductor substrates including cores optimized for coefficient of thermal expansion (CTE) matching, and/or the like. A buffer layer 104 comprising one or more layers of III-N semiconductor material is formed on the substrate 102. In some examples where the substrate 102 is implemented as a silicon wafer or a sapphire wafer, the buffer layer 104 may include a nucleation layer having a stoichiometry that includes aluminum to match a lattice constant of the substrate 102. In versions of some examples, the buffer layer 104 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 104, are not specifically shown in the drawing Figures of the present disclosure.

Depending on implementation, the buffer layer 104 may have a thickness of about 1 micron (μm) to several microns, e.g., 3.5 μm to 7.0 μm, which may be formed by a suitable epitaxial process, e.g., a metal organic vapor phase epitaxy (MOVPE) process with several operations to form the various layers and/or sublayers. In some arrangements, an example buffer layer 104 may comprise a stack of multiple layers/sublayers of suitable materials and compositions (e.g., GaN, AlGaN) as noted above, where the layers/sublayers may have variable thicknesses depending on the technology and device application. In some arrangements, the buffer layer 104 may include AlGaN-based transition layers, epitaxial layers with strain-layer superlattice (SLS) structures, and the like.

Depending on the sizing of the GaN device 101, the buffer layer 104 may be formed to overlap an area of the substrate 102, where different regions such as a source region 105A, a gate region 105B, a drain region 105D and a drain access region 105C between the gate region 105B and the drain region 105D may be provided with respect to the GaN device 101. A channel layer may be provided as part of the buffer layer 104—e.g., a top portion of the buffer layer 104 proximate to a barrier layer 110. Whereas a channel layer may primarily include GaN material, there may be optional trace amounts of other group III elements, such as aluminum or indium, in some implementations.

A barrier layer 110 comprising III-N semiconductor material is formed over the buffer layer 104. In an example arrangement, the barrier layer 110 may have a thickness ranging from about 1 nanometer (nm) to about 60 nm, and may include aluminum and nitrogen. In some versions of this example, the barrier layer 110 may include gallium at a lower atomic percent than aluminum. In some versions, the barrier layer 110 may also include indium. In some examples, the barrier layer 110 includes an AlGaN layer.

The barrier layer 110 over the buffer layer 104 is operable as part of a heterojunction structure 106 for causing the formation of a 2DEG 108 proximate to an interface between the barrier layer 110 and the buffer layer 104. In some examples, the stoichiometry and thickness of the barrier layer 110 may be configured to provide a suitable free charge carrier density (e.g., 3×10¹² cm⁻² to 2×10¹³ cm⁻²) of the 2DEG for facilitating the device operation.

For purposes of effectuating EMODE functionality, a p-doped III-N (p-III-N, p-GaN) layer 114, e.g., comprising one or more layers of III-N material, is formed over the barrier layer 110 as shown in FIG. 1A. The formation of the p-GaN layer 114 causes the 2DEG to be reduced—e.g., absent in some cases. In versions of this example, the p-doped III-N layer 114 may comprise a GaN layer doped with magnesium (Mg) or other p-type dopants. In some examples, the p-doped GaN layer 114 may include a peak p-dopant concentration of about 1×10²⁰ atoms/cm³, and may have a thickness of about 50 nm to 200 nm. In some additional and/or alternative arrangements, additional layers such as an AlGaN cap layer (e.g., devoid of p-doping; not shown in the Figures) may be provided over the p-GaN layer 114.

FIG. 1B depicts a stage after patterning the p-GaN layer 114 using a gate stack mask and appropriate photolithography and etch process to form a part of a gate stack 112, which may include additional layers in some implementations. As a result of patterning the p-GaN layer 114 (e.g., removing portions of the p-GaN layer 114 outside the gate region 105B), the 2DEG 108 may be established in the channel layer outside the gate region 105B. In versions of the examples herein, the source region 105A (where a source electrode or contact comprising a DTS is be formed) and the drain region 105D (where a drain electrode or contact is to be formed) are asymmetrically disposed relative to the gate region 105B although it is not a requirement. For example, there may be a greater lateral distance between the gate region 105B and the drain region 105D than a lateral distance between the gate region 105B and the source region 105A by virtue of an access region, e.g., drain access region 105C, disposed between the gate region 105B and the drain region 105D. In some additional and/or alternative arrangements, a source access region may also be provided between the source region 105A and the gate region 105B in a similar manner while still having source/drain region asymmetry with respect to the gate region 105B.

FIG. 1C depicts a stage where a dielectric layer 116 is formed over the gate stack 112. In some examples, the dielectric layer 116 may have a thickness of about 50 nm to 100 nm, and may comprise silicon dioxide (SiO₂), silicon oxynitride (SiON), silicon nitride (SiN), aluminum oxide (AlO), and the like, deposited in a CVD process.

FIG. 1D depicts a stage where a contact aperture or opening 118 having a suitable form factor and dimensions (e.g., including rectangular shapes, square shapes, etc.) is formed in the drain region 105D of the device 101. The aperture 118 may be formed by etching or removing the material from the dielectric layer 116 and the barrier layer 110 over the buffer layer 104, e.g., using a contact mask and a pattern etch process comprising wet etch and/or dry etch, thus exposing the buffer layer 104 in the drain region 105D.

FIG. 1E depicts a stage where a trench 120 having a suitable form factor and dimensions (e.g., including rectangular shapes, square shapes, etc.) is formed in the source region 105A of the device 101, which is extended into the substrate 102 by a suitable depth depending on implementation. In some examples, the trench 120 may be formed by a high aspect ratio etch (HARE) process. In some examples, the trench 120 may have a depth 125 from a top surface of the barrier layer 110 to a bottom 121 of the trench 120 extending into the semiconductor substrate 102. In some examples, the trench 120 may have a width 123 that is a fraction of the depth 125. In some examples, the depth 125 may range from about 0.1 μm to about 10 μm. Depending on implementation, the trench 120 may have an aspect ratio where the depth 125 is greater than at least three times the width 123.

In an example implementation, the trench 120 may be formed using an etch process based on inductively-coupled plasma (ICP) deep reactive ion etching (DRIE), without limitation. Although the formation of a single trench, e.g., trench 120, is shown in the cross-sectional view of FIG. 1E, some additional and/or alternative examples may have multiple trenches, e.g., having corresponding dimensions and form factors, formed in the source region 105A, that extend into the substrate 102. Further, DRIE processes having different etch rates, chemistries, etc. may be implemented for different layers/sublayers of the buffer layer stack 104, depending on implementation. In still further arrangements, the source region 105A of the GaN device 101 may include one or more source contact apertures (not shown in FIG. 1E) in addition to the trench(es) 120, where the source contact apertures extend only to the buffer layer 104 for facilitating the formation of source contacts that are not connected to the semiconductor substrate 102.

FIG. 1F depicts a stage where a DTS contact or electrode 122A and a drain contact or electrode 122B are formed using a suitable metallization process. Depending on implementation, the DTS contact 122A and the drain contact 122B may include one or more metals, such as titanium, nickel, tungsten, platinum, iridium, aluminum, gold, etc., and/or may include other electrically conductive material such as carbon nanotubes or graphene. The DTS contact 122A may comprise a first contact 124A configured to make contact (e.g., ohmic contact) with the 2DEG 108 of the heterojunction structure 106 and to make a second contact 124B at or near the bottom 121 of the trench 120 configured to make contact (e.g., ohmic contact) with the semiconductor substrate 102. Although the DTS contact 122A is depicted as completely filled with the one or more metals, the DTS contact 122A may include one or more seams (e.g., voids, cavities) depending on the aspect ratio of the trench 120 and characteristics of metal deposition steps, in some examples. By way of example, such a seam may extend to the top of the DTS contact 122A. In other examples, such a seam may be enclosed (e.g., sealed off) within the DTS contact 122A.

FIG. 1G depicts a stage where a dielectric layer 130 of suitable thickness and composition is formed over the GaN device 101. In versions of this example, the dielectric layer 130 is operable to mask and protect the DTS contact 122A and the drain contact 122B from subsequent processing, e.g., gate electrode formation.

FIG. 1H depicts a stage where a gate electrode photolithography and etch process is performed to form an aperture 132 that exposes the p-GaN layer 114 of the gate stack 112. FIG. 1I depicts a stage where gate electrode (or contact) 122C is formed using suitable metallization process. Similar to the formation of the DTS contact 122A and the drain contact 122B, the gate electrode 122C may include metals such as titanium, nickel, tungsten, platinum, iridium, aluminum, etc., and/or other electrically conductive material such as carbon nanotubes or graphene.

In FIG. 1J, a cross-sectional view of a more completely formed semiconductor device 100 including the GaN device 101 is illustrated. As depicted, a dielectric layer 140, e.g., operable as an inter-level dielectric (ILD) and/or pre-metal dielectric (PMD) insulator, is formed over the GaN device 101. In some implementations, the dielectric layer 140 may comprise multiple layers having different compositions, e.g., SiN, SiO, etc., with a total thickness ranging from about 0.5 μm to about 5 μm. A contact photolithography and etch process may be configured to pattern contact openings in the dielectric layer 140 over the source region 105A, the gate region 105B (not shown) and the drain region 105D. A source terminal or contact 144A extending through the dielectric layer 140 is formed for making electrical contact with the DTS electrode 122A in the source region 105A. In similar manner, a drain terminal or contact 144B is formed through the dielectric layer 140 for making electrical contact with the drain electrode 122B. Although a gate terminal is also formed for contacting with the gate electrode 122C, it is not shown in FIG. 1J as it is not coplanar with the sectional plane passing through the source and drain terminals 144A and 144B, as provided herein for purposes of illustration. Depending on implementation, the source and drain terminals 144A, 144B may comprise various metals and/or other conductive materials, which may be similar to the composition of the DTS electrode 122A, the drain electrode 122B, and the gate electrode 122C, although it is not a requirement.

Although the DTS contact 122A is shown in FIG. 1F as a filled structure, some additional and/or alternative examples may have a DTS contact that contains a cavity (e.g., a seam, a void), which may be formed as a result of the formation of a wider trench in the source region 105A—e.g., depending on the aspect ratio of the trench 120 and characteristics of metal deposition steps forming the DTS contact 122A, as noted previously. In general, the presence or absence of a trench cavity may depend upon the device design, e.g., trench aspect ratios, metal thickness, and/or the GaN epitaxy stack thickness that needs to be etched through, etc. In some arrangements, the cavity in a DTS contact (if present) may be filled in with one or more dielectric materials in subsequent stages, which may be removed in a backend metallization process for forming respective terminals in the source, drain and gate regions as set forth above. As a result, the cavity in a DTS contact (if present) may be at least partially filled with one or more dielectric materials, one or more metals, or a combination thereof.

In some additional and/or alternative arrangements, various portions of a DTS contact, e.g., the DTS contact 122A, may be fabricated using different metals, e.g., a first metal for forming the first contact 124A with the 2DEG 108 and a second metal for forming the second contact 124B with the semiconductor substrate 102 as shown in FIG. 1K. In such arrangements, separate masks may be used for forming bottom and top portions of the DTS contact 122A, where different metals may be deposited for contact formation, e.g., platinum for contacting with the semiconductor substrate 102 and tungsten for contacting with the 2DEG 108 of the GaN device 101. In some representative versions of this example, a first metal may be deposited in the trench, which may be patterned by using a first mask and metal etch process for forming a substrate contact (e.g., portion 150B including the second contact 124B). In some arrangements, the first metal mask may be sized appropriately relative to the trench sizing. A second metal may be deposited in the partially filled trench for forming a contact with respect to the 2DEG 108 (e.g., portion 150A including the first contact 124A), including an overburden for facilitating the fabrication of the DTS electrode over the heterojunction structure 106. A second mask and metal etch process may be used for patterning the second metal, forming a complete DTS contact structure in the source region of the GaN device 101. As will be set forth below, analogous two-metal DTS contact structures may be provided in other examples of the present disclosure.

FIGS. 2A-2H depict cross-sectional views of a semiconductor device 200 including a GaN device 201 at various stages of another “gate last” process flow according to a further example of the present disclosure. In general, the stages shown in FIGS. 2A-2H are substantially similar or identical to several corresponding stages shown in FIGS. 1A-1K. Accordingly, the description set forth above regarding FIGS. 1A-1K is largely applicable, in relevant parts, to the various corresponding structures and features illustrated in the cross-sectional view of FIGS. 2A-2H, which will not be repeated in detail here except as will be noted below.

Similar to the stages shown in FIGS. 1A-1C, an intermediate stage of the semiconductor device 200 includes a semiconductor substrate 202 where a source region 205A, a gate region 205B, a drain region 205D and a drain access region 205C between the gate region 205B and the drain region 205D may be provided with respect to the GaN device 201. A gate stack 212 including a p-GaN layer 214 is formed over a heterojunction structure 206 disposed over the substrate 202. As before, the heterojunction structure 206 includes a barrier layer 210 over a buffer layer 204, which supports a 2DEG 208 in the buffer layer 204, proximate to an interface between the barrier layer 210 and the buffer layer 204. A dielectric layer 216 is formed over the barrier layer 210 and the gate stack 212 in the stage shown in FIG. 2C. In versions of this example, the dielectric layer 216 is operable to protect the p-GaN gate 214 during the subsequent process stages of DTS and drain contact formation.

Whereas the trench formation stage in FIG. 1E involves fabricating a trench having uniform vertical profile (e.g., straight profile) such as the trench 120, the example GaN device 201 includes a “stepped” trench, where the trench profile may include a shallow upper portion that is wider than a deeper lower portion, forming a ledge or rim in the trench profile. In some versions of this example, a first portion of the trench (e.g., an upper portion) may be provided for facilitating a wider source contact (e.g., a greater perimeter) configured to contact the 2DEG 208 at a shallow ledge (e.g., having a greater contact boundary), whereas a second portion (e.g., a lower portion) may be provided for facilitating a deeper, narrower substrate contact configured to contact the substrate 202.

FIG. 2D depicts a stage where respective contact apertures or openings are formed in the source and drain regions 205A, 205B for facilitating the formation of a shallow wide portion of a stepped trench in the source region. As illustrated, a first contact aperture 218A is formed in the source region 205A and a second contact aperture 218B is formed in the drain region 205D, similar to the drain contact aperture formation stage shown in FIG. 1D. Whereas both contact apertures 218A and 218B may be formed in a single contact photolithography and etch process, it is not a requirement for purposes of some examples of the present disclosure. In some examples, the first contact aperture 218A may at least partially extend into the buffer layer 204—e.g., to further facilitate electrical connections to the 2DEG 208.

FIG. 2E depicts a stage where a trench 220 is formed in the source region 205A, the trench being narrower than the first contact aperture 218A and extending into the semiconductor substrate 202 by a suitable depth. In some examples, the etch process for forming the first contact aperture 218A in the stage shown in FIG. 2D may remove the barrier layer 210, exposing the buffer layer 204 of the heterojunction structure 206, although it is not a necessary requirement. Regardless of whether the barrier layer 210 is completely removed in the formation of the first contact aperture 218A, a ledge 227 is formed proximate to the 2DEG 208. Further, similar to the trench 120 shown in FIG. 1E, the stepped profile trench 220 may have an overall depth 225 from a top surface of the barrier layer 210 to a bottom 221 of the trench 220, where the depth 225 may be greater than at least three times a width 223 of the trench 220. Although a single-step trench 220 is illustrated in FIG. 2E, additional and/or alternative arrangements may include forming a multi-step trench (e.g., a trench with multiple ledges) in the source region 205A using appropriate mask/etch processes.

FIG. 2F depicts a contact metallization stage analogous to the stage shown in FIG. 1F, where a DTS contact or electrode 222A and a drain contact or electrode 222B are formed in the source and drain regions 205A, 205B, respectively. Because of the ledge 227 adjacent to the 2DEG 208, a top surface of the DTS contact 222A may have different topography than a top surface of the drain contact 222B, although it is not a necessary requirement. Further, where multiple ledges are formed in the trench profile, one or more ledges may be disposed adjacent to the 2DEG 208 in some examples. Similar to the DTS contact 122A, the DTS contact 222A includes a first contact 224A configured to contact the 2DEG 208 and a second contact 224B configured to contact the semiconductor substrate 202.

FIG. 2G depicts a dielectric deposition stage analogous to the stage shown in FIG. 1G, where a suitable dielectric layer 230 is formed over the DTS contact 222A, the drain contact 222B and the gate stack 212. Thereafter, a gate contact etch stage and a gate metallization stage may follow similar to the stages depicted in FIGS. 1H and 1I, where a gate contact or electrode is formed. In FIG. 2H, a cross-sectional view of a more completely formed semiconductor device 200 including the GaN device 201 is illustrated, which is similar to the semiconductor device 100 shown in FIG. 1J, save for the first contact 224A with the 2DEG 208 having a wider profile than the second contact 224B contacting the semiconductor substrate 202, among others. Further, similar to the structure shown in FIG. 1J, the GaN device 201 may be provided with a source terminal 244A, a drain terminal 244B and a gate terminal (not shown) formed through an ILD/PMD layer 240 for facilitating electrical contact with DTS electrode 222A, drain electrode 222B and gate electrode 222C, respectively.

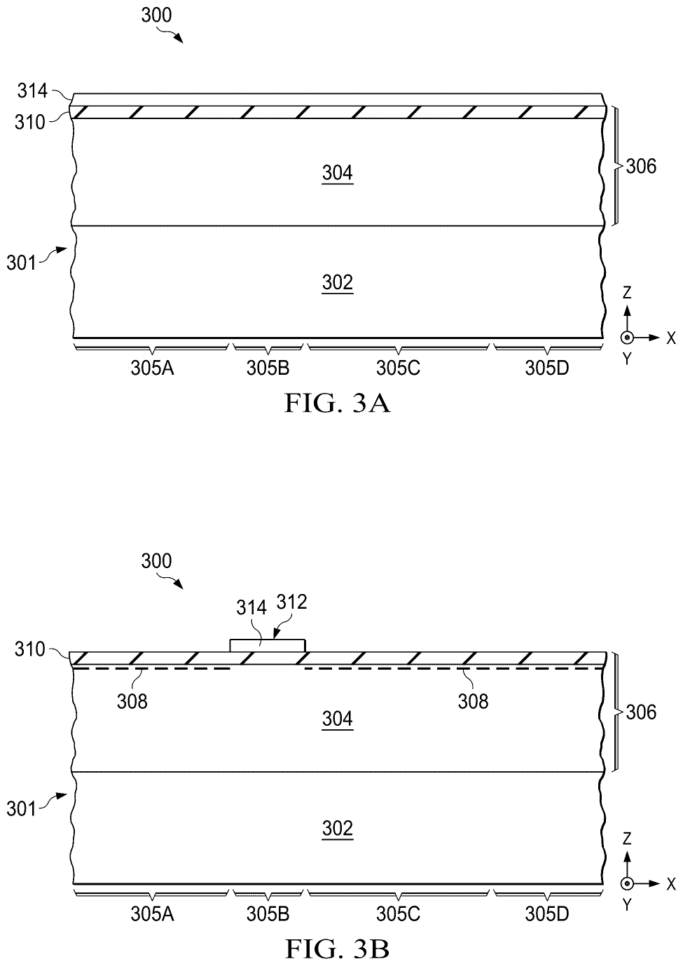

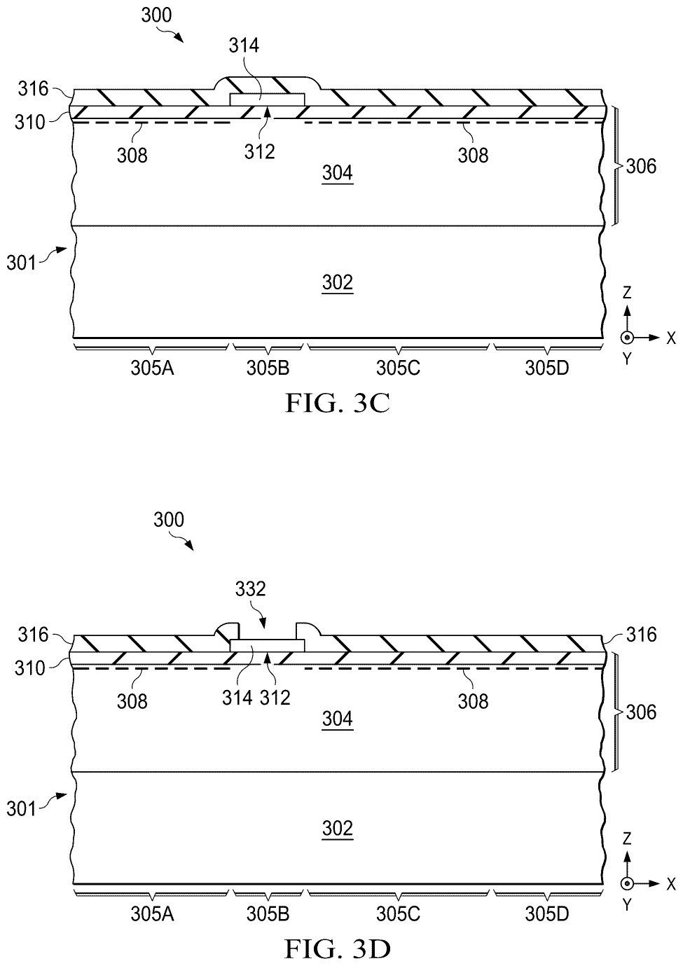

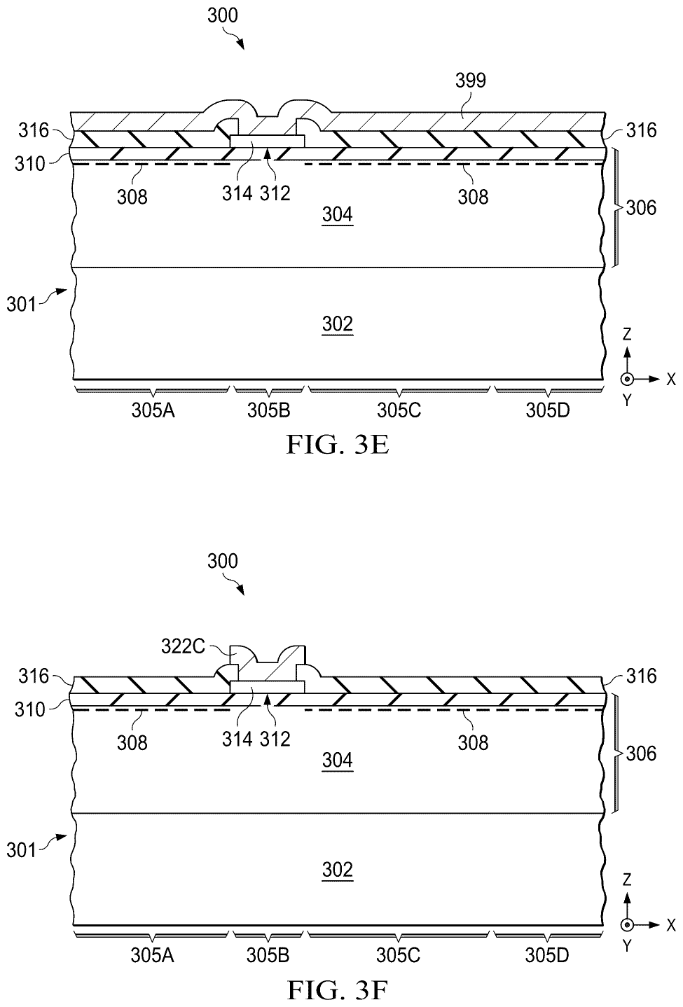

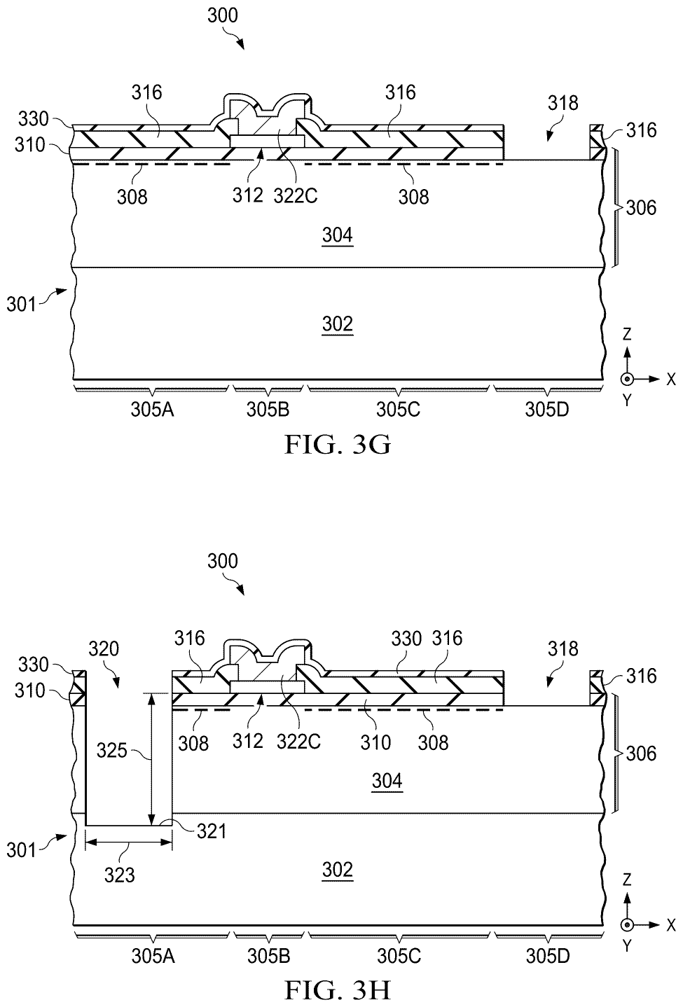

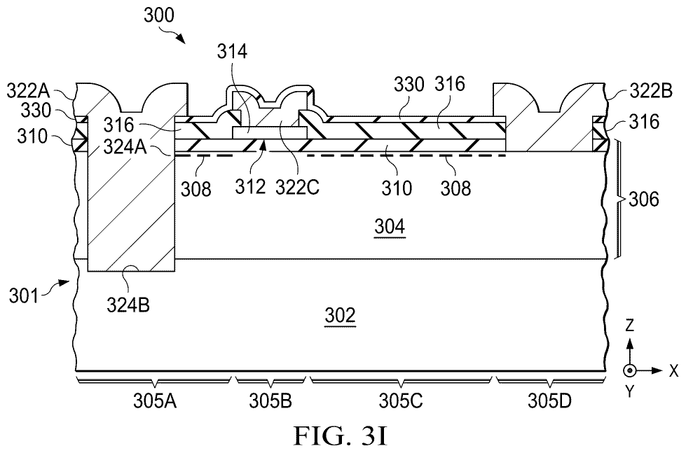

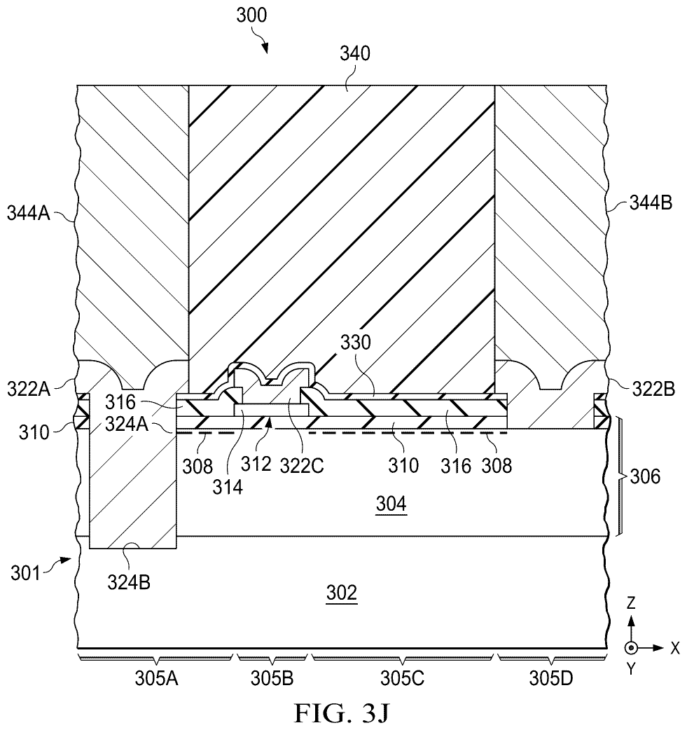

FIGS. 3A-3J depict cross-sectional views of a semiconductor device 300 including a GaN device 301 at various stages of a “gate first” process flow for integrating a DTS contact according to an example of the present disclosure. As with the stages shown in FIGS. 2A-2H described above, the stages shown in FIGS. 3A-3J are also substantially similar or identical to several corresponding stages shown in FIGS. 1A-1K. Accordingly, the description set forth above with respect to FIGS. 1A-1K and/or FIGS. 2A-2H is also applied here, in relevant parts, to the various corresponding structures and features illustrated in the cross-sectional view of FIGS. 3A-3J, which will not be repeated in detail here except as will be noted below.

Similar to the stages shown in FIGS. 1A-1C and/or FIGS. 2A-2C, an intermediate stage of the semiconductor device 300 includes a semiconductor substrate 302 where a source region 305A, a gate region 305B, a drain region 305D and a drain access region 305C between the gate region 305B and the drain region 305D may be provided with respect to the GaN device 301. A gate stack 312 including a p-GaN layer 314 is formed over a heterojunction structure 306 disposed over the substrate 302. As before, the heterojunction structure 306 includes a barrier layer 310 over a buffer layer 304, which supports a 2DEG 308 in the buffer layer 304, proximate to an interface between the barrier layer 310 and the buffer layer 304. A dielectric layer 316 is formed over the barrier layer 310 and the gate stack 312 in the stage shown in FIG. 3C.

Prior to forming DTS and drain contact structures as described above, an example “gate first” flow includes forming a gate electrode in the gate region 305B first, which is facilitated by forming a gate contact aperture 332 in the gate stack 312 as depicted in FIG. 3D. In versions of this example, a gate contact photolithography and etch process similar to the stage shown in FIG. 1H may be performed to form the aperture 332 that exposes the p-GaN layer 314 of the gate stack 312. FIG. 3E depicts a stage where a suitable conductive layer 399 is formed over the device regions. In versions of this example, the conductive layer 399 may comprise a metal layer formed by sputtering.

FIG. 3F depicts a stage where a gate electrode 322C is patterned from the gate metal layer 399 based on a suitable gate lithography and etch process. FIG. 3G depicts a stage where a dielectric layer 330 is first deposited over the device regions and thereafter a drain contact aperture 318 is formed in the drain region 305D, similar to the dielectric deposition and drain contact etch process stages set forth above. In versions of this example, the dielectric layer 330 is operable to mask the gate electrode 322C during subsequent process stages involving DTS and drain contact formation.

FIGS. 3H and 3I depict trench formation and DTS and drain contact formation stages, respectively. Similar to the trench 120 shown in FIG. 1E, a trench 320 having suitable dimensions and form factor(s) is formed in the source region 305A, which extends into the semiconductor substrate 302 by a suitable depth, as depicted in FIG. 3H. In some additional and/or alternative arrangements, a shallow wider etch followed by a deep trench process may be implemented for forming a stepped trench in the source region 305A, similar to the process stages of FIGS. 2D and 2E. Further, the trench 320 may have a depth 325 greater than at least three times a width 323, as previously set forth, where a bottom 321 of the trench 320 extends into the semiconductor substrate 302. In FIG. 3I, a DTS contact or electrode 322A and a drain contact or electrode 322B are formed in the trench 320 and the drain contact aperture 318, respectively, similar to the process stage depicted in FIG. 1F. As before, the DTS contact 322A includes a first contact 324A configured to contact the 2DEG 308 and a second contact 324B configured to contact the semiconductor substrate 302.

In FIG. 3J, a cross-sectional view of a more completely formed semiconductor device 300 including the GaN device 301 is illustrated, which is similar to the semiconductor device 100 shown in FIG. 1J. Further, analogous to the structure shown in FIG. 1J, the GaN device 301 may be provided with a source terminal 344A, a drain terminal 344B and a gate terminal (not shown) formed through an ILD/PMD layer 340 for facilitating electrical contact with DTS electrode 322A, drain electrode 322B and gate electrode 322C, respectively.

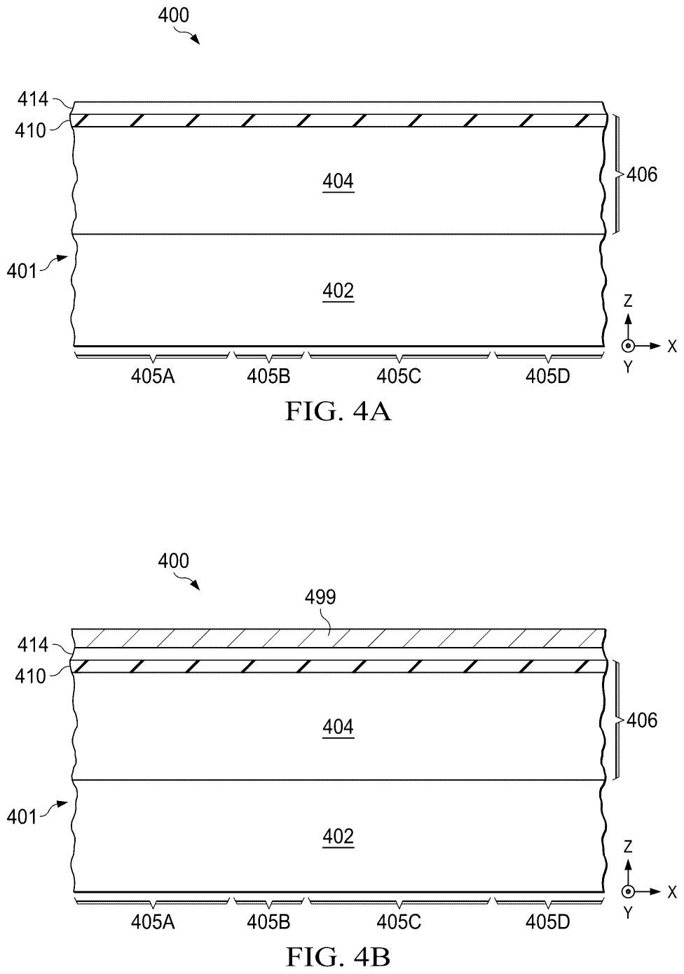

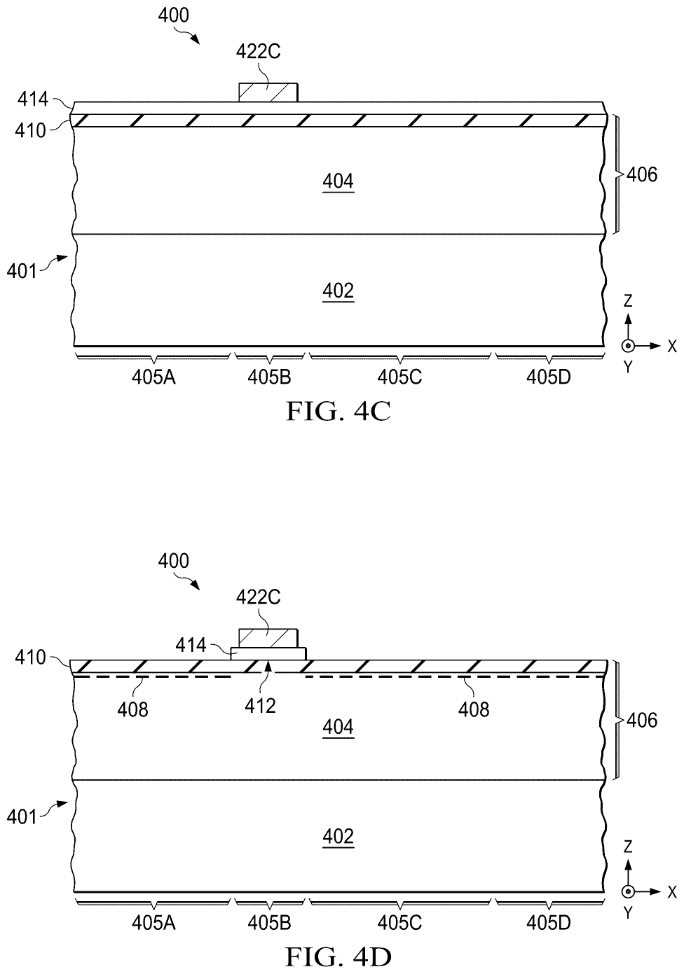

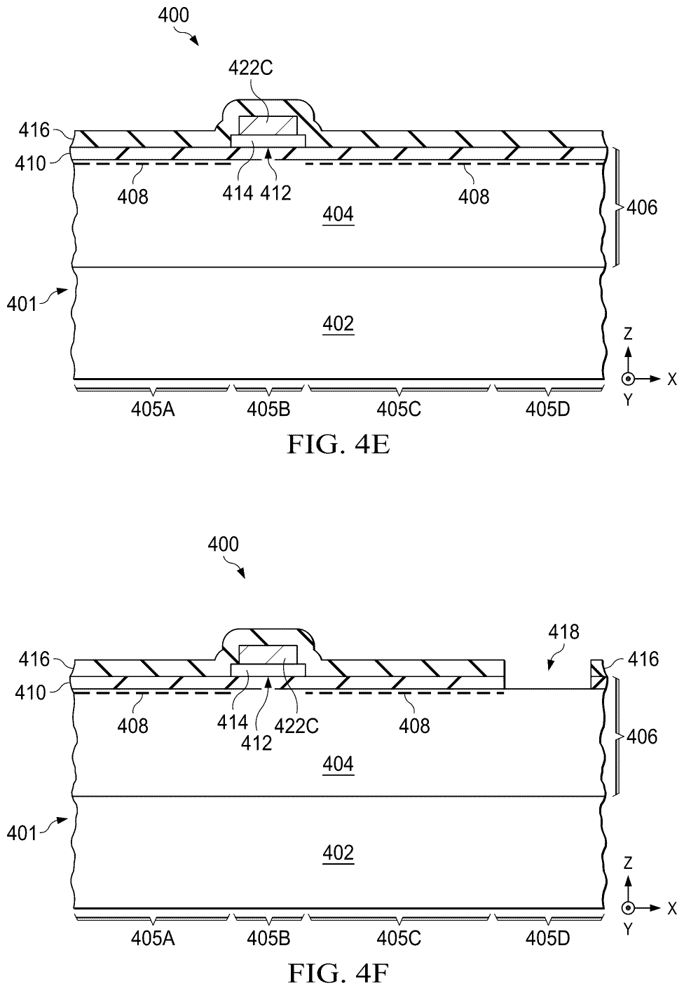

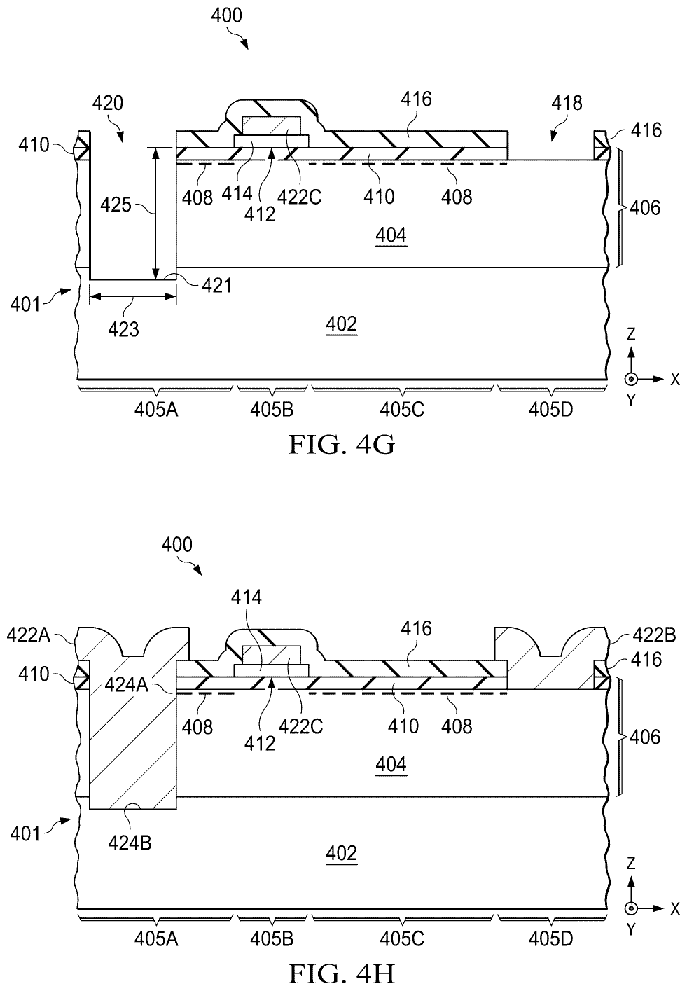

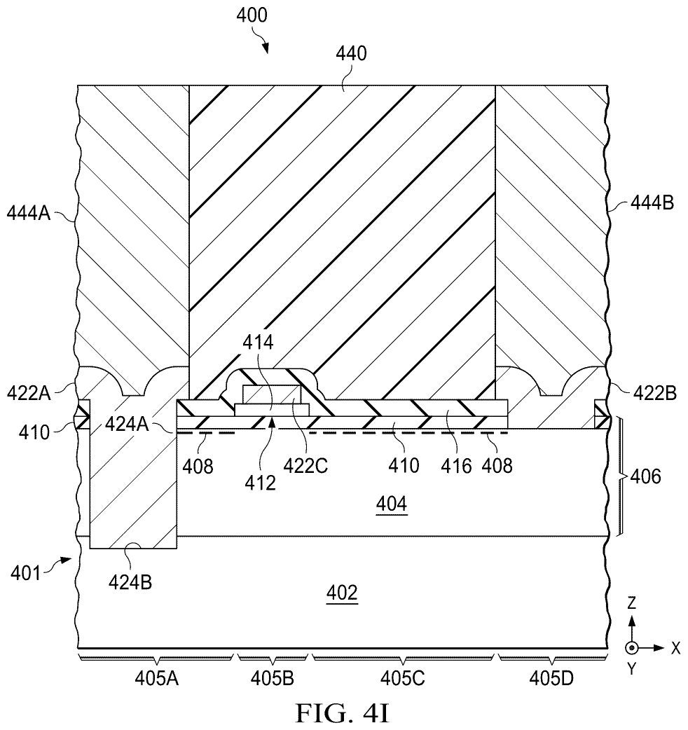

FIGS. 4A-4I depict cross-sectional views of a semiconductor device 400 including a GaN device 401 at various stages of another example “gate first” process flow for integrating a DTS contact according to the present disclosure. Compared with the stages set forth above in FIG. 3A-3J, where the p-GaN layer 314 is patterned independent of and prior to forming a gate electrode (e.g., in a non-self-aligned gate formation scheme), the example flow set forth in FIGS. 4A-4I illustrates a self-aligned gate formation scheme where a p-GaN layer may be patterned and etched along with a gate metal layer. Aside from the foregoing variation, the stages of FIGS. 4A-4I are generally analogous to the corresponding stages shown in FIGS. 3A-3J described above, which in turn are similar to the relevant corresponding stages of FIGS. 1A-1K as previously set forth. Accordingly, the description set forth above with respect to FIGS. 1A-1K and/or FIGS. 3A-3J is also applied here, in relevant parts, to the various corresponding structures and features illustrated in the cross-sectional view of FIGS. 4A-4I, which will not be repeated in detail here except as will be noted below.

Similar to the stages shown in FIGS. 1A, 2A, and 3A, an early intermediate stage of the semiconductor device 400 shown in FIG. 4A includes a semiconductor substrate 402 where a source region 405A, a gate region 405B, a drain region 405D and a drain access region 405C between the gate region 405B and the drain region 405D may be provided with respect to the GaN device 401. Analogous to the examples described above, a heterojunction structure 406 includes a barrier layer 410 over a buffer layer 404, which supports a 2DEG 408 in the barrier layer 410 proximate to an interface between the barrier layer 410 and the buffer layer 404. A p-GaN layer 414 is formed over the heterojunction structure 306 disposed over the semiconductor substrate 402.

FIG. 4B depicts a stage where a gate metal layer 499 is formed (e.g., sputtered) over the p-GaN layer 414 similar to the stage shown in FIG. 3E. Thereafter, the gate metal layer 499 may be etched to form a gate electrode 422C in the gate region 405B, as shown in FIG. 4C. In versions of this example, the same mask used for patterning the gate metal layer 499 may be used for etching the p-GaN layer 414 to form a gate, forming a gate stack 412 over the barrier layer 410 in the gate region 405B. In some arrangements, sidewall spacers (not shown) may be provided on each side of the gate electrode 422C prior to etching the p-GaN layer 414. Accordingly, the p-GaN gate 414 may be patterned to be wider than the gate electrode 422C in an example arrangement as shown in FIG. 4D (with the sidewall spacers removed).

FIG. 4E depicts a dielectric deposition stage where a dielectric layer 416 having suitable thickness and composition is formed over the device regions. FIG. 4F depicts a stage where a contact aperture or opening 418 is formed in the drain region 405D similar to the stage set forth in FIG. 1D.

FIGS. 4G and 4H depict trench formation and DTS and drain contact formation stages, respectively. Similar to the trench 120 shown in FIG. 1E, a trench 420 having suitable dimensions and form factor(s) is formed in the source region 405A, which extends into the semiconductor substrate 402 by a suitable depth, as depicted in FIG. 4E. Further, the trench 420 may have a depth 425 greater than at least three times a width 423, as previously set forth, where a bottom 421 of the trench 420 extends into the semiconductor substrate 402. In FIG. 4H, a DTS contact or electrode 422A and a drain contact or electrode 422B are formed in the trench 420 and the drain contact aperture 418, respectively, similar to the process stage depicted in FIG. 1F. In versions of this example, the DTS contact 422A therefore includes a first contact 424A configured to contact the 2DEG 408 and a second contact 424B configured to contact the semiconductor substrate 402.

In FIG. 4I, a cross-sectional view of a more completely formed semiconductor device 400 including the GaN device 401 is illustrated, which is similar to the semiconductor device 100 shown in FIG. 1J. Further, analogous to the structure shown in FIG. 1J, the GaN device 401 may be provided with a source terminal 444A, a drain terminal 444B and a gate terminal (not shown) formed through an ILD/PMD layer 440 for facilitating electrical contact with DTS electrode 422A, drain electrode 422B and gate electrode 422C, respectively.

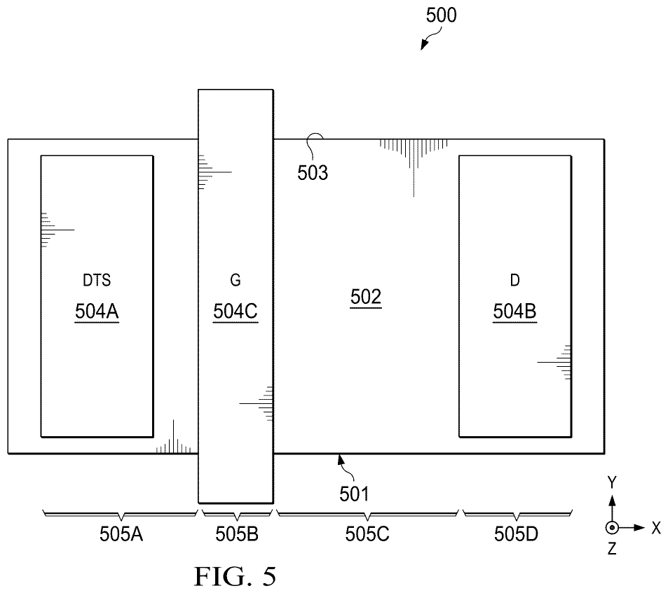

FIG. 5 depicts a layout of a semiconductor device 500 according to some examples of the present disclosure where a GaN unit cell 501 comprises an area 502 (e.g., an active area, a device area, etc.) including a single DTS contact structure. The area 502 may be defined by an isolation boundary 503 formed by any suitable isolation process. The area 502 includes a source region 505A, a gate region 505B, a drain region 505D and a drain access region 505C disposed between the gate region 505B and the drain region 505D. A single DTS contact 504A having a rectangular shape is provided in the source region 505A, where the DTS contact 504A extends into a substrate underlying the active area 502 (e.g., along the Z-axis orthogonal to the X-Y layout plane). A drain contact 504B and a gate contact 504C are provided in the drain region 505B and the gate region 505B, respectively.

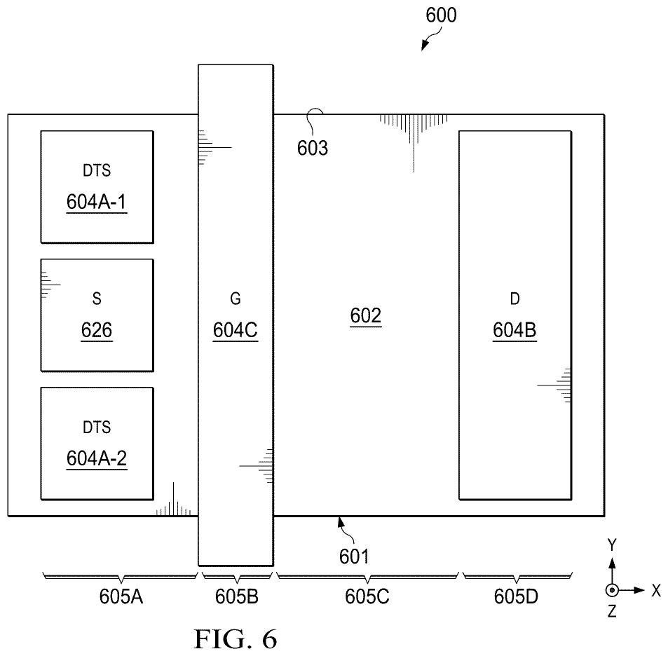

FIG. 6 depicts a layout of a semiconductor device 600 according to some examples of the present disclosure where a GaN unit cell 601 comprises an area 602 including multiple DTS contact structures in a hybrid source architecture. For purposes herein, a hybrid source architecture in some examples may refer to a unit cell having at least one DTS contact in addition to a source contact not tied to a substrate (e.g., a non-DTS source contact comprising an independent source contact extending to a buffer layer (e.g., buffer layers 104, 204, 304, 404) above a substrate of the device). In some additional and/or alternative examples, a hybrid source architecture may refer to a semiconductor device comprising multiple unit cells, where at least one unit cell may include an independent source contact (e.g., a non-DTS source contact) in any combination with one or more DTS contacts on a per-cell basis as will be set forth below.

Continuing to refer to FIG. 6, the area 602 of the GaN unit cell 601 may be surrounded by an isolation boundary 603 that may be formed by any suitable isolation process similar to the unit cell structure shown in FIG. 5. The area 602 includes a source region 605A, a gate region 605B, a drain region 605D and a drain access region 605C disposed between the gate region 605B and the drain region 605D. By way of illustration, two DTS contacts 604A-1, 604A-2 having a square shape are provided in the source region 605A, where the DTS contacts 604A-1, 604A-2 each extend into a substrate underlying the area 602 by way of respective trenches. A drain contact 604B and a gate contact 604C are provided in the drain region 605B and the gate region 605B, respectively. In addition to the DTS contacts 604A-1, 604A-2, the source region 605A includes an independent source contact 626 (e.g., a non-DTS source contact).

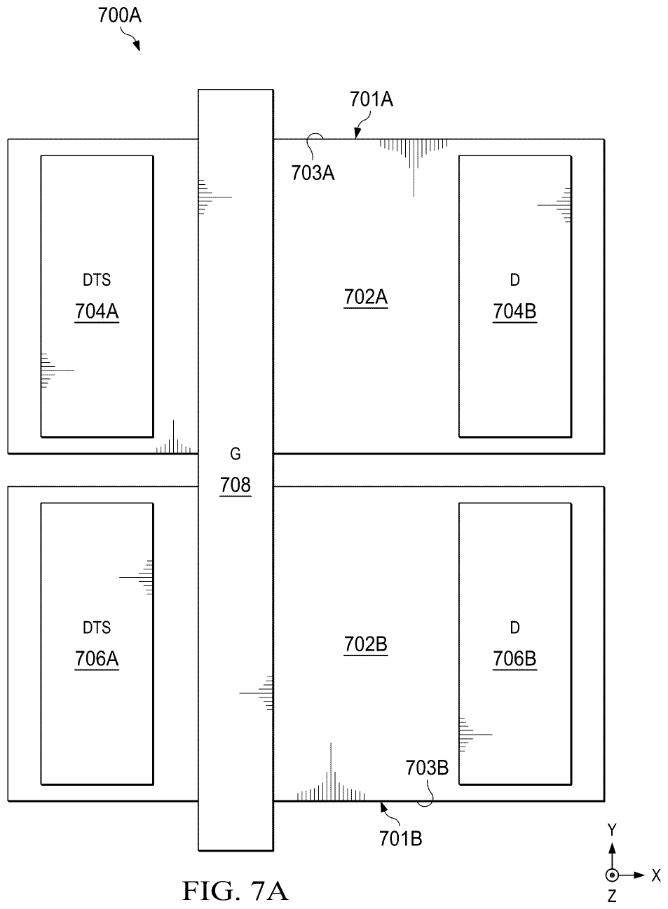

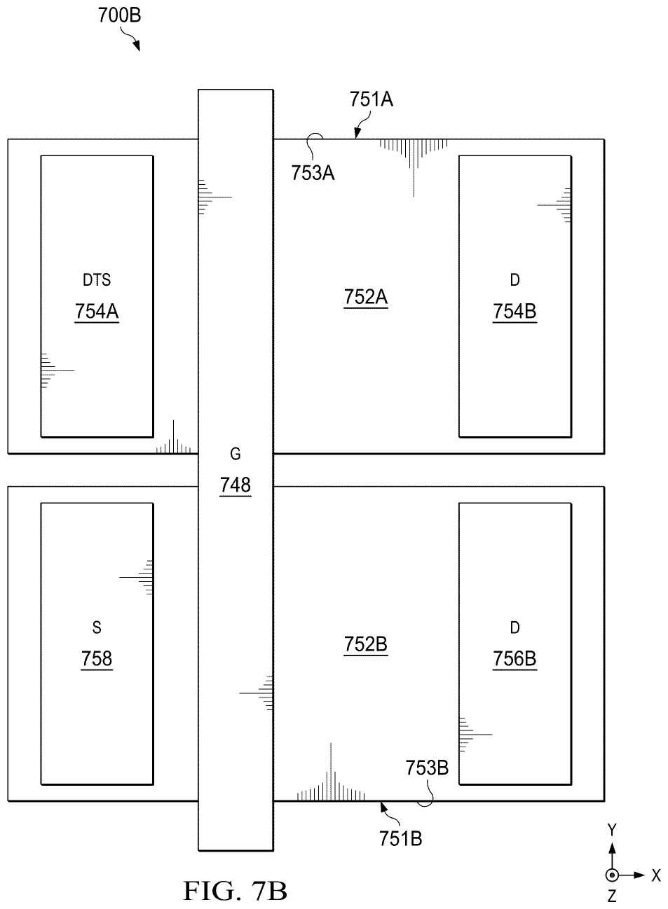

FIGS. 7A and 7B depict layouts of semiconductor devices including multiple unit cells according to some examples of the present disclosure. In FIG. 7A, an example semiconductor device 700A comprises two GaN unit cells 701A, 701B, each including a respective area 702A, 702B separated by isolation boundaries 703A, 703B similar to the GaN unit cells 501 and 601 set forth above. A single DTS contact 704A, 706A is provided in respective source regions of the GaN unit cells 701A, 701B, that extends into the semiconductor substrate similar to the DTS contact 504A of GaN unit cell 501 set forth above. Likewise, drain contacts 704B, 706B are provided in respective drain regions of the GaN unit cells 701A, 701B, which are commonly coupled by a shared gate contact structure 708.

FIG. 7B depicts a semiconductor device 700B comprising multiple unit cells based on a hybrid source architecture where one of the unit cells may include an independent source contact not tied to a substrate. As illustrated, the semiconductor device 700B comprises two GaN unit cells 751A, 751B, each including a respective area 752A, 752B separated by isolation boundaries 753A, 753B similar to the arrangement shown in FIG. 7A. A single DTS contact 754A and a single independent source contact 758 are provided in respective source regions of the GaN unit cells 751A, 751B. Further, drain contacts 754B, 756B are provided in respective drain regions of the GaN unit cells 751A, 751B, which are commonly coupled by a shared gate contact structure 758 analogous to the semiconductor device 700A shown in FIG. 7A.

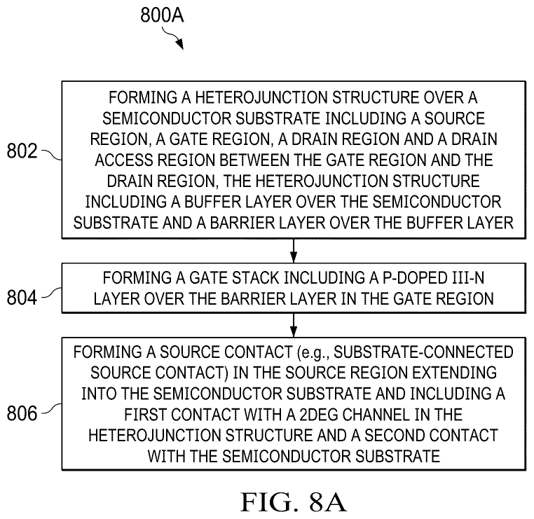

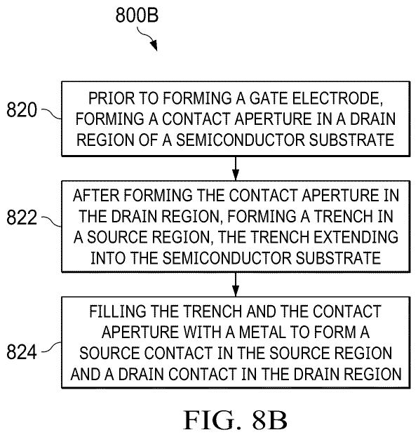

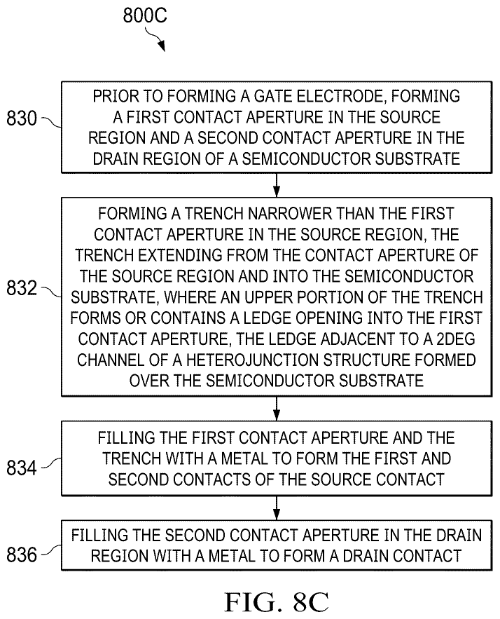

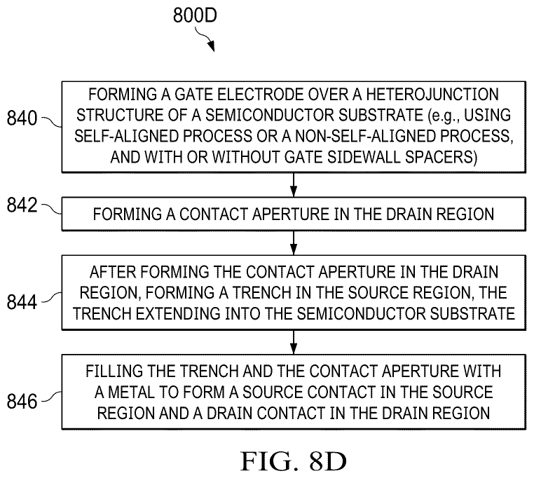

FIGS. 8A-8D are flowcharts of methods of fabricating a semiconductor device including a GaN device having a deep trench source according to some examples of the present disclosure, where different steps, acts, functions and/or blocks may be combined or otherwise rearranged in multiple combinations. Method 800A shown in FIG. 8A may commence with forming a heterojunction structure over a semiconductor substrate including a source region, a gate region, a drain region, and a drain access region between the gate region and the drain region (block 802). As previously set forth with respect to the process stages shown in FIGS. 1A-4A, the heterojunction structure includes a buffer layer over the semiconductor substrate and a barrier layer over the buffer layer. At block 804, a gate stack including a p-doped III-N layer may be formed over the barrier layer in the gate region. At block 806, a source contact (e.g., a DTS contact or a substrate-connected contact) is formed in the source region, which extends into the semiconductor substrate and includes a first contact with a 2DEG in the heterojunction structure and a second contact with the semiconductor substrate, as set forth previously with respect to the process stages shown in FIGS. 1E-1F; 2E-2F; 3H-3I; and 4G-4H.

In some arrangements, a contact aperture may be formed in a drain region of a semiconductor substrate prior to forming a gate electrode, as set forth in block 820 of method 800B, which relates to some aspects of the process stages shown in FIGS. 1D and 2D. After forming the contact aperture in the drain region, a trench may be formed in a source region, where the trench extends into the semiconductor substrate as set forth at block 822, which relates to some aspects of the process stages shown in FIGS. 1E and 2E. Thereafter, the trench and the drain contact aperture may be filled with a metal to form a source contact (e.g., a DTS contact) in the source region and a drain contact in the drain region, as set forth at block 824, which relates to some aspects of the process stages shown in FIGS. 1F and 2F.

In some arrangements, prior to forming a gate electrode, a first contact aperture and a second contact aperture may be formed in the source and drain regions, respectively, as set forth at block 830 of method 800C, which relates some aspects of the process stage shown in FIG. 2D. At block 832, a trench narrower than the first contact aperture may be formed in the source region, where the trench extends from the contact aperture of the source region and into the semiconductor substrate, which relates to some aspects of the process stage shown in FIG. 2E. As previously set forth, an upper portion of the trench may contain or form a ledge opening into the first contact aperture, where the ledge is adjacent to a 2DEG of a heterojunction structure formed over the semiconductor substrate. At block 834, the first contact aperture and the trench may be filled with a metal to form first and second contacts of a source contact (e.g., a DTS contact). At block 836, the second contact aperture may be filled with a metal to form a drain contact. In some examples, the foregoing blocks 834 and 836 may relate to some aspects of the process stage shown in FIG. 2F.

In some arrangements, a gate electrode may be formed over a heterojunction structure before the fabrication of source and drain contacts, where the gate electrode may be patterned using a self-aligned process or a non-self-aligned process, as set forth at block 840 of method 800D. In versions of this example, the acts set forth at block 840 may relate to some aspects of the process stages shown in FIGS. 3D-3F and FIGS. 4B-4D, where sidewall spacers may be used in a self-aligned process as previously set forth. At block 842, a contact aperture may be formed in the drain region. Thereafter, a trench extending into the semiconductor substrate may be formed in the source region (block 844). Subsequently, the trench and the contact aperture may be filled with a metal to form a source contact (e.g., a DTS contact) and a drain contact in the source and drain regions, respectively, as set forth at block 846. In some examples, the acts set forth at blocks 842-844 may relate to the process stages shown in FIGS. 3G-3I and FIGS. 4F-4H described above.

While various examples of the present disclosure have been described above, they have been presented by way of example only and not limitation. For example, although a DTS contact is illustrated in an EMODE GaN transistor in the forgoing example, such a DTS contact may be included in a DMODE GaN transistor (e.g., a DMODE GaN transistor without a p-GaN layer in its gate stack). Further, a self-aligned gate formation process (e.g., similar to the arrangement set forth above in reference to FIGS. 4A-4I) may be implemented in conjunction with a gate last process described above (e.g., in the arrangements of FIGS. 1A-1J and FIGS. 2A-2H) in additional and/or alternative examples—e.g., forming a source contact (e.g., a DTS contact) and a drain contact in the source and drain regions, respectively, through a p-GaN layer, and then removing the p-GaN layer during a self-aligned gate formation process using a gate-metal mask patterning a gate metal layer and the p-GaN layer. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, and a drain access region between the gate region and the drain region;
a heterojunction structure over the semiconductor substrate, the heterojunction structure including a buffer layer over the semiconductor substrate and a barrier layer over the buffer layer;
a gate stack over the barrier layer in the gate region; and
a source contact in the source region extending into the semiconductor substrate and including a first contact with a 2DEG in the heterojunction structure and a second contact with the semiconductor substrate.

2. The semiconductor device of claim 1, wherein the source contact is disposed in a trench having an aspect ratio with a depth greater than at least three times a width of the trench.

3. The semiconductor device of claim 1, wherein the source contact is a first source contact, and wherein the source region further comprises a second source contact extended to the buffer layer.

4. The semiconductor device of claim 1, wherein the first contact of the source contact comprises a first metal and the second contact of the source contact comprises a second metal different from the first metal.

5. The semiconductor device of claim 1, wherein the first contact of the source contact comprises a first portion connected to the 2DEG and the second contact of the source contact comprises a second portion narrower than the first portion, the second portion connected to the semiconductor substrate.

6. The semiconductor device of claim 1, wherein the gate stack includes a p-doped III-N layer over the barrier layer.

7. The semiconductor device of claim 6, further including a gate electrode aligned to the p-doped III-N layer of the gate stack.

8. A method, comprising:
forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer;
forming a gate stack over the barrier layer in the gate region; and
forming a source contact in the source region extending into the semiconductor substrate and including a first contact with a 2DEG in the heterojunction structure and a second contact with the semiconductor substrate.

9. The method of claim 8, wherein the source contact is formed before forming a gate electrode coupled to the gate stack.

10. The method of claim 9, further comprising:
forming a contact aperture in the drain region;
after forming the contact aperture in the drain region, forming a trench in the source region, the trench extending into the semiconductor substrate; and
forming the source contact in the trench and a drain contact in the contact aperture.

11. The method of claim 9, further comprising forming a first contact aperture in the source region and a second contact aperture in the drain region.

12. The method of claim 11, further comprising forming a trench narrower than the first contact aperture in the source region, the trench extending into to the semiconductor substrate.

13. The method of claim 12, further comprising filling the first contact aperture and the trench with a metal to form the first and second contacts of the source contact.

14. The method of claim 11, further comprising filling the second contact aperture in the drain region with a metal to form a drain contact.

15. The method of claim 8, wherein the source contact is formed after forming a gate electrode coupled to the gate stack.

16. The method of claim 15, wherein the gate stack includes a p-doped III-N layer, and wherein the gate electrode is patterned during patterning of the p-doped III-N layer.

17. The method of claim 15, further comprising:
forming a contact aperture in the drain region;
after forming the contact aperture in the drain region, forming a trench in the source region, the trench extending into the semiconductor substrate; and
forming the source contact in the trench and a drain contact in the contact aperture.

18. A semiconductor device, comprising:
a first III-N unit cell formed over a first area of a semiconductor substrate, the first III-N unit cell including a first source contact in a source region of the first area, wherein the first source contact is connected to the semiconductor substrate through a trench extended into the semiconductor substrate; and
a second III-N unit cell formed over a second area of the semiconductor substrate, the second III-N unit cell including a second source contact in a source region of the second area, wherein the first and second III-N unit cells are coupled together with a common gate.

19. The semiconductor device of claim 18, wherein the second source contact is connected to the semiconductor substrate through another trench extended into the semiconductor substrate.

20. The semiconductor device of claim 18, wherein the second source contact extends to a III-N buffer layer over the semiconductor substrate.
